(19) United States
(12) Patent Application Publication
(10) Pub. No.: US 2021/0066239 A1
(43) Pub. Date: Mar. 4, 2021

(54) PACKAGED SEMICONDUCTOR DEVICES WITH UNIFORM SOLDER JOINTS

(71) Applicant: Texas Instruments Incorporated, Dallas, TX (US)

(72) Inventor: Steffany Ann Lacierda Moreno, Bamban (PH)

(21) Appl. No.: 16/559,410

(22) Filed: Sep. 3, 2019

(51) Int. Cl. H01L 23/00; H01L 21/56; H01L 23/495

(52) U.S. Cl. CPC H01L 24/81; H01L 2224/81815; H01L 24/13; H01L 24/16; H01L 24/97; H01L 21/561; H01L 23/49541; H01L 23/4951; H01L 2224/13147; H01L 2224/10175; H01L 2224/1357; H01L 2224/1416; H01L 2224/16245; H01L 2224/81191; H01L 2224/81395; H01L 24/14

(57) ABSTRACT

An example apparatus includes a semiconductor die including a bond pad; a conductive post on the bond pad; a solder joint electrically connecting the conductive post to a substrate; and ink residue of solder mask material surrounding a portion of the solder joint, the ink residue covering a portion of the substrate. Methods for forming the apparatus are disclosed.

### TECHNICAL FIELD

This disclosure relates generally to packaged semiconductor dies, and more particularly to packaged semiconductor dies with solder bump joints.

### SUMMARY

In a described example, an apparatus includes a semiconductor die including a bond pad; a conductive post on the bond pad; a solder joint electrically connecting the conductive post to a substrate; and ink residue of solder mask material surrounding a portion of the solder joint, the ink residue covering a portion of the substrate. In another example, a method includes ink-jet depositing material forming an ink residue surrounding a portion of a solder joint area and covering a portion of a surface of a substrate; bringing a solder bump that is atop a conductive post coupled to an semiconductor die into contact with the solder joint area; and melting the solder bump and forming a solder joint between the conductive post and the surface of the substrate, the solder joint partially surrounded by the ink residue.

### BRIEF DESCRIPTION OF THE DRAWINGS

FIG. 1 illustrates a cross sectional view of an arrangement including a packaged semiconductor device including a die with uniform solder joints surrounded with a solder mask.

FIG. 2 illustrates a cross sectional view of a packaged semiconductor device with non-uniform solder joints.

FIG. 3 illustrates another cross sectional view of a packaged semiconductor device with non-uniform solder joints.

FIGS. 4A-4D are top down views illustrating the major steps in forming uniform solder joints between a semiconductor die and leads on a substrate.

FIGS. 4AA-4DD are cross sectional views of the steps in forming uniform solder joints between a semiconductor die and leads on a substrate.

FIG. 5 is a projection view of a quad., flat, no lead (QFN) packaged semiconductor device.

FIGS. 6A-6E are cross sectional views of selected steps for forming packaged semiconductor devices with uniform solder joints between a semiconductor die and leads on a substrate.

FIG. 7 is a flow diagram describing the process steps in FIGS. 6A-6E.

### DETAILED DESCRIPTION

Corresponding numerals and symbols in the different figures generally refer to corresponding parts, unless otherwise indicated. The figures are not necessarily drawn to scale.

Elements are described herein as “coupled.” As used herein, the term “coupled” includes elements that are directly connected and includes elements that are electrically connected with intervening elements or wires, these elements are also coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, or active devices such as transistors. The semiconductor device can be an integrated circuit with hundreds or thousands of transistors coupled to form a functional circuit, for example a microprocessor or memory device. The semiconductor device can be a passive device such as a sensor, example sensors include photocells, transducers, and charge coupled devices (CCDs), or can be a micromechanical device, such as a digital micromirror device (DMD) or a micro electro-mechanical system (MEMS) device. The term “semiconductor die” is used herein. A semiconductor die is a device that is formed using semiconductor processing with other semiconductor devices on a semiconductor substrate, such as a silicon wafer, and then is separated from the semiconductor wafer and the other devices to form an individual semiconductor die.

The term “substrate” is used herein. A substrate is a component used in mounting and packaging a semiconductor die. Examples shown in the figures herein show a pre-molded lead frame (PMLF) as the substrate. In addition, useful substrates for the arrangements include conductive lead frames, partially etched or half-etched conductive lead frames, and molded interconnect substrates (MIS). The substrate can be a film, laminate or tape that carries conductors, or can be a printed circuit board such as reinforced fiber glass (FR4), bismaleimide triazine (BT) resin, alumina, silicon carbide, or aluminum nitride. The materials for the substrate can include conductors such as copper and copper alloys, iron-nickel alloys such as Alloy 42, and gold and gold alloys. Gold, silver, palladium, nickel and tin platings can be made on the metal conductors. These platings improve solderability, bondability, reduce diffusion and reduce possible corrosion. The substrates can include dielectrics including silicon, glass, mold compound, ceramic, polyimide, fiberglass, and resins. Multiple levels of conductors spaced from one another by dielectric layers and conductive vias forming conductive connections between the multiple conductor levels can be used in the substrates.

The term “solder mask” is used herein. As used herein, solder mask is a material applied to a surface to prevent solder from depositing on the surface in the areas covered by the solder mask. Openings in the solder mask allow solder connections to conductive areas on the surface. In an example a solder joint is to be made between a semiconductor die having a conductive pillar on a bond pad and a conductive land on the substrate. Solder mask can be deposited on the substrate around the conductive land that the solder joint will be formed on.

In this description, the term “ink jet deposition” is used. Ink jet deposition is an additive manufacturing process for depositing a material on a surface. In printing, the term “ink jet printing” is used for additive deposition of ink using nozzles to dispense the ink as drops in patterns to form characters and symbols on a surface. In industrial applications, ink jet nozzles can deposit materials in an additive deposition to form layers on a surface. Ink jet deposition uses many fine nozzles coupled to ink reservoirs that include an electrical actuator. A piezoelectric actuator in a reservoir can force a small known volume of liquid material through a nozzle in response to an electrical signal. A thermal ink jet nozzle has a resistive element in the reservoir which heats and expands the ink to force a known volume of ink through a nozzle. In both cases as the ink falls the surface tension causes a spherical drop to form. Because the ink jet nozzles are so fine and because the nozzles include forming a drop in response to an electrical signal, the term “drop on demand” or “DOD” is used to describe the ability of ink jet deposition tools to precisely deposit a small quantity of liquid as the nozzle travels relative to a surface (moving either the surface or the nozzle with respect to the other). This precise drop placement results in a very efficient use of material to accurately place the material and reduces waste and removes the need for cleaning or etching steps to remove unwanted material from portions of the surface. Masking and patterning steps are not needed with ink jet deposition, in contrast to sputtering or other deposition methods. Removal of excess or unneeded material is also eliminated when ink jet deposition is used to deposit material. The ink jet ink can have a viscosity between about 2 and 20 centipoise.

In this description, the term “ink residue” is used. Ink residue is material deposited in liquid form by ink jet deposition or by screen deposition that may then be cured to form a solid layer, and the material is referred to herein as “ink residue.” Because the material can be very accurately placed even in small areas, no etch or material removal step is needed to remove ink residue material after the ink jet deposition. Also, the material is used very efficiently with little waste when compared to spin coating, squeegee coating, screen deposition (sometimes referred to as “screen printing”) or slit print deposition processes.

In this description, elements are described as having “uniform thickness.” In manufacturing, some deviation in thickness of elements can occur and this deviation can cause some slight differences in thickness between the elements. If two elements are intended to have a uniform thickness, as used herein the two elements have uniform thickness, even though some manufacturing deviations can and do occur.

In the arrangements, the problem of non-uniform solder joint thickness among solder joints for a semiconductor die mounted to a substrate is solved by forming solder mask around an intended solder joint area on the substrate, so that the later formed solder joint connection remains within the intended area. The resulting solder joints are uniform in thickness and in addition, solder bridging that can occur when the solder mask is not present is reduced or eliminated. In an example method, the solder mask is an ink residue surrounding a portion of the intended solder joint area on the surface of the substrate. The ink residue is formed prior to mounting the semiconductor die and prior to forming the solder connections. In additional arrangements, the ink residue solder mask material is selectively formed around selected solder joints known to be areas on the substrate where non-uniform solder joints may otherwise form when the semiconductor die is later mounted to the substrate. In these additional arrangements, some areas where solder joints are to be formed are left without the ink residue, where the ink residue is not needed to control the solder when the solder joints are formed.

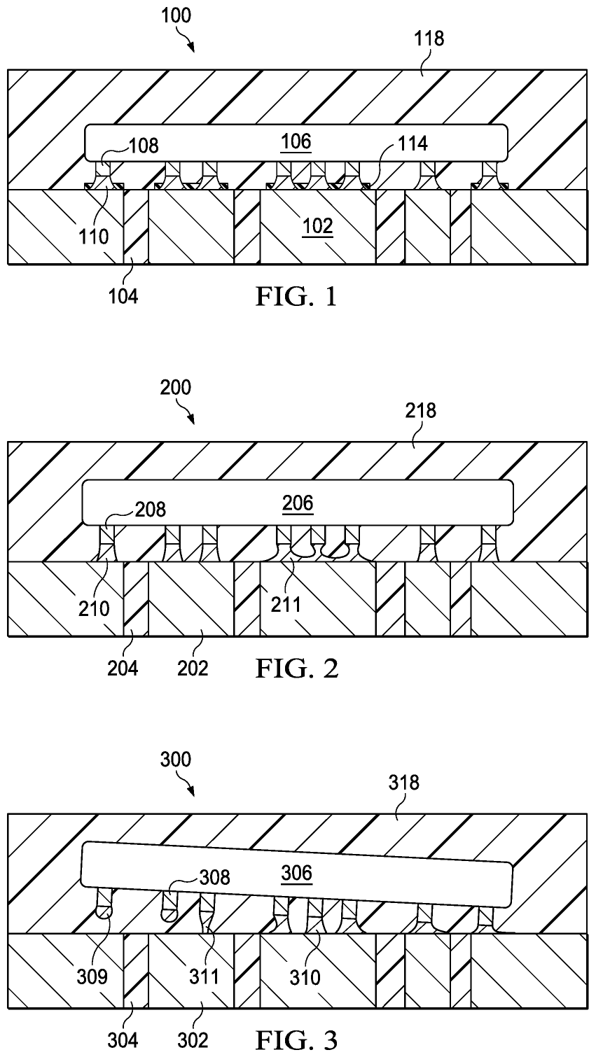

FIG. 1 is a cross sectional view of an example arrangement including a packaged semiconductor die 100 with uniform thickness solder joints 110 formed between the semiconductor die 106 and a substrate 102. The substrate 102 in the example of FIG. 1 is a pre-molded lead frame (PMLF) with a pre-mold material 104, such as a filled epoxy, occupying the spaces between conductive leads. A solder mask 114 made of a polymeric material covers the surface of the substrate 102 around solder joints 110 that electrically couple the conductive posts 108 on semiconductor die 106 to the lead on the substrate 102. Conductive posts 108 such as a copper post or pillar or a copper alloy post or pillar have an end covered with solder. The combined copper (or copper alloy) pillar 108 and solder can be referred to as a copper pillar solder bump, a copper pillar bump, or a solder cap. In the examples presented herein, the conductive posts 108 are copper posts. Conductive posts 108 such as copper posts can be formed on the semiconductor die 106 using a plating process such as electroplating or electroless plating. In alternatives other conductive posts or posts plated with conductive material can be used. The solder mask 114 covers a portion of the leads on the substrate 102 where multiple solder joints are to be made to multiple copper posts 108 and optionally covers a portion of the leads where a single solder joint 110 is to be made to a single copper post 108. The solder joints 110 and copper posts 108 form electrical connections between leads on the substrate 102 and the semiconductor die 106.

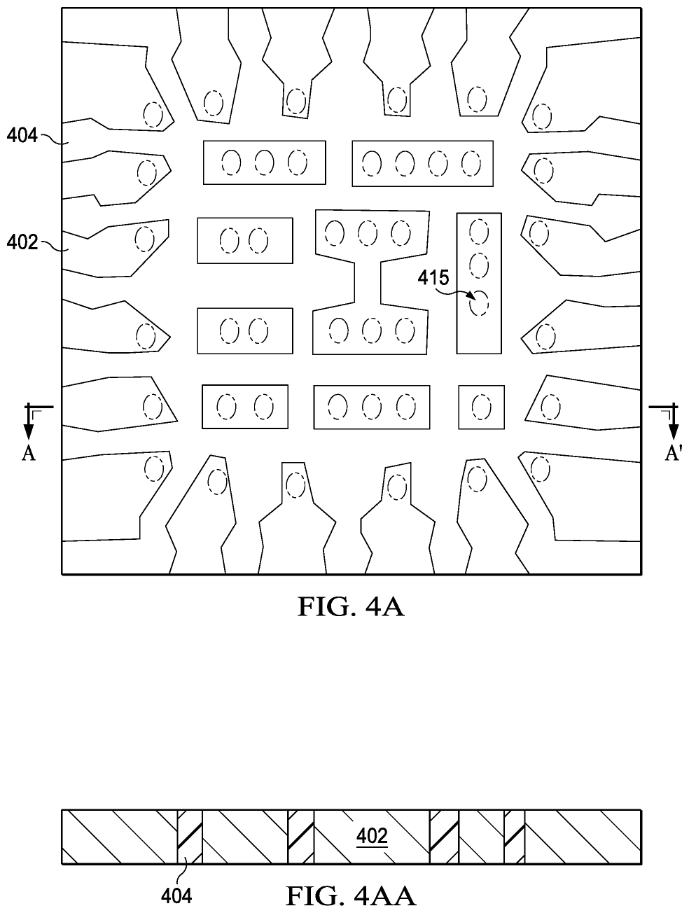

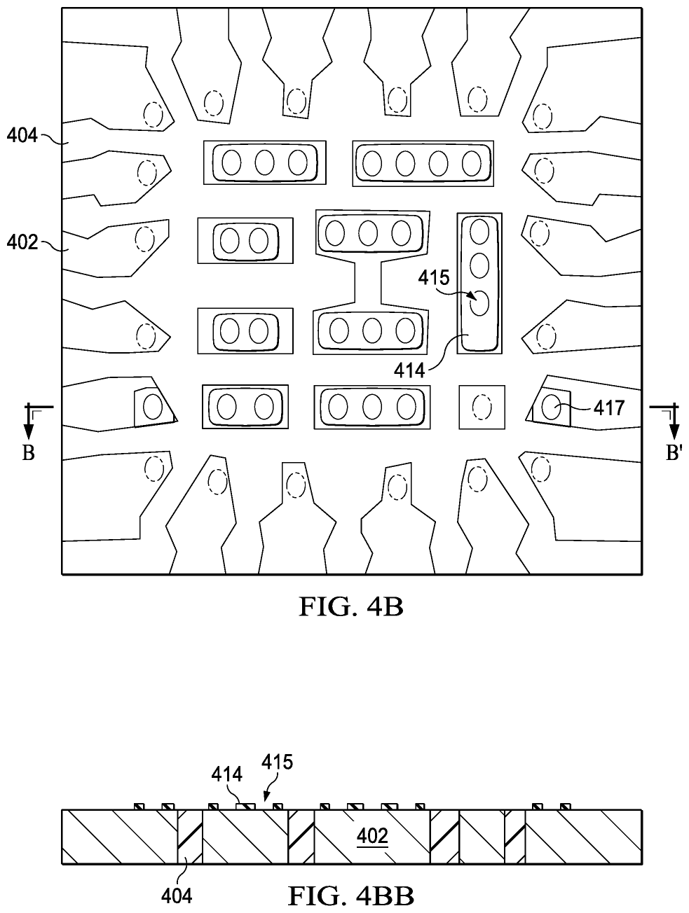

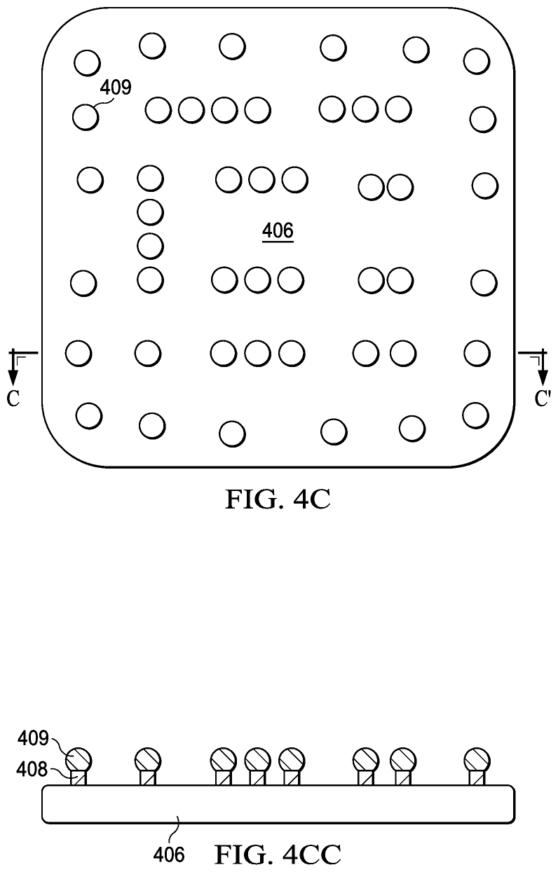

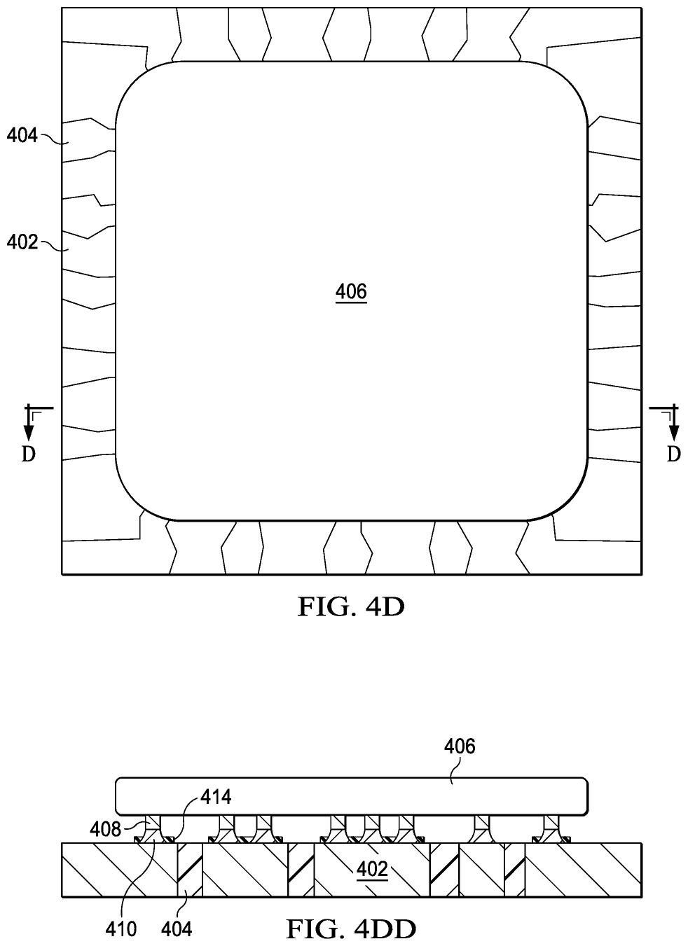

In this example, mold compound 118 covers a portion of the surface of the substrate 102, the solder mask 114, the solder joints 110, the copper posts 108 and the semiconductor die 106 to form the packaged semiconductor device 100. In the arrangements, various mold compounds used for semiconductor packaging can be used, for example mold compound 118 can be filled or non-filled thermoset epoxy resin, or alternatively a room temperature liquid mold compound can be used which is subsequently cured. Thermally conductive fillers can be used to improve heat transfer of the mold compound. Other fillers can be used to strengthen the mold compound. The solder mask 114 prevents solder on the copper posts 108 from flowing outside the intended solder joint area during the die mounting procedure when solder bumps (also referred to as solder caps) 409 (see FIG. 4DD) on the ends of the copper posts 108 are melted in a thermal reflow process to form solder joints 110.

FIG. 2 shows in another cross sectional view a packaged semiconductor device 200 that does not have a solder mask. In FIG. 2 similar reference labels are used for similar elements as are shown in FIG. 1, for clarity. For example, substrate 202 in FIG. 2 corresponds to the substrate 102 in FIG. 1. During a thermal reflow process when the solder joints are formed using the solder bumps or caps on the conductive posts, lack of a solder mask in the packaged semiconductor device 200 allows solder to wet the surface of the lead on the substrate 202, and this allows solder to flow away from the intended solder joint area. Solder flows away from the intended solder joint area causing solder joints 211 with reduced diameter to form. These reduced diameter solder joints are weaker and more resistive (compared to a solder joint that stays within the intended solder joint area). The weakened and resistive solder joints 211 can cause reliability failures in the field.

FIG. 3 shows another cross sectional view of a packaged semiconductor device 300 that does not have a solder mask. In FIG. 3 similar reference labels are used for similar elements as are shown in FIG. 1, for clarity. For example, substrate 302 in FIG. 3 corresponds to substrate 102 in FIG. 1. Lack of a solder mask allows solder 311 to flow non-uniformly under the various copper posts 308 across the surface of leads in the substrate 302 during a die mounting process. This results in solder joints, such as 310 and 311, forming with different thicknesses between the substrate 302 and the semiconductor die 306. The different thickness solder joints 310 and 311 can result in die tilt (as shown, die 306 is not parallel to the surface of the substrate 302). As illustrated in FIG. 3, die tilt of die 306 in some instances can be so severe that some solder bumps 309 fail to form solder joints 310, while other solder bumps 309 form weak solder joints 311 with reduced diameter. When these opens or weak solder joints occur, the packaged semiconductor device 300 fails and may have to be scrapped.

FIGS. 4A-4D are top down views that illustrate the steps of an example arrangement for forming a packaged semiconductor die 100 (see FIG. 1) with uniform solder joints in more detail. FIGS. 4AA-4DDD are cross sections taken through the substrates 402 in FIGS. 4A-4D. In FIGS. 4A-4D and 4AA-4DD similar reference labels are used for similar elements as are shown in FIG. 1, for clarity. For example, substrate 402 in FIGS. 4A-4D and 4AA-4DD correspond to substrate 102 in FIG. 1.

FIG. 4A is a top down view of a representative substrate 402, in this example substrate 402 is a PMLF. The spaces between the conductive leads on substrate 402 are filled with pre-mold compound 404. Regions 415 on the surface of the substrate 402 indicate places where solder joints 410 (see FIG. 4DD) between the copper posts 408 on the semiconductor die 406 and leads on substrate 402 are to be formed during the die mounting procedure. FIG. 4AA is a cross section taken through the substrate 402 in FIG. 4A along dashed line A-A′.

FIG. 4B is a top down view of the substrate 402 in FIG. 4A with solder mask 414 covering the surface of leads around areas where multiple solder joints 410 (see FIG. 4DD) are to be formed. Solder mask is selectively applied around areas where single solder joints 417 are to be formed. The solder mask 414 prevents solder 409 on copper pillars or posts 408 on the semiconductor die 406 from wetting the surface of the substrate 402 outside the solder joint area 415. Solder is prevented from flowing away during the solder reflow process and weakening the resulting solder joint 410. FIG. 4BB is a cross section of the substrate 402 in FIG. 4B taken along dashed line B-B′ through the substrate 402 and through the solder mask 414. Note in FIG. 4B, the solder joint areas where solder mask is not applied are shown in dashed lines, while the solder joint areas where solder mask is applied are shown as solid lines to differentiate these solder joint areas. Areas where solder is known to deposit uniformly and without excess wetting are optionally left without the solder mask material. Alternatively, the solder mask material can be deposited around all the solder joint areas to form an additional arrangement.

FIG. 4C is a top down view of the device side of the semiconductor die 406 with solder bumps 409 that will be melted in a thermal reflow process to form solder joints 410 (FIG. 4D) to the substrate 402 during a die mounting procedure. FIG. 4CC is a cross section view of the semiconductor die 406 in FIG. 4C taken along dashed line C-C′. The solder bumps 409 sit atop copper posts 408 that provide electrical connection to semiconductor die 406.

FIG. 4D is a top down view of the substrate 402 on which the semiconductor die 406 is mounted. FIG. 4DD is a cross section of the substrate 402 in FIG. 4D taken along dashed line D-D′. During the die mounting process, the solder bumps 409 are brought into contact with the solder joint regions 415 on the substrate that are surrounded by the solder mask 414. The solder bumps 409 are then melted to form solder joints 410 to the surface of the lead frame 402. By preventing the solder from flowing outside the solder joint regions 415, the solder mask 414 enables the formation of solder joints that are uniform in thickness.

The upper surface of the substrate 402 (as oriented in FIG. 4DD), the solder joints 410, the solder mask 414, the copper posts 408 and the semiconductor die 406 are then at least partially covered with mold compound 118 (see FIG. 1) to form the packaged semiconductor device 100 with uniform thickness solder joints 110. Note that some areas of some leads of the substrate 102 are not covered with mold compound, to allow exposed conductive portions of the conductive leads on the substrate 102 to form external terminals of the packaged semiconductor device 100.

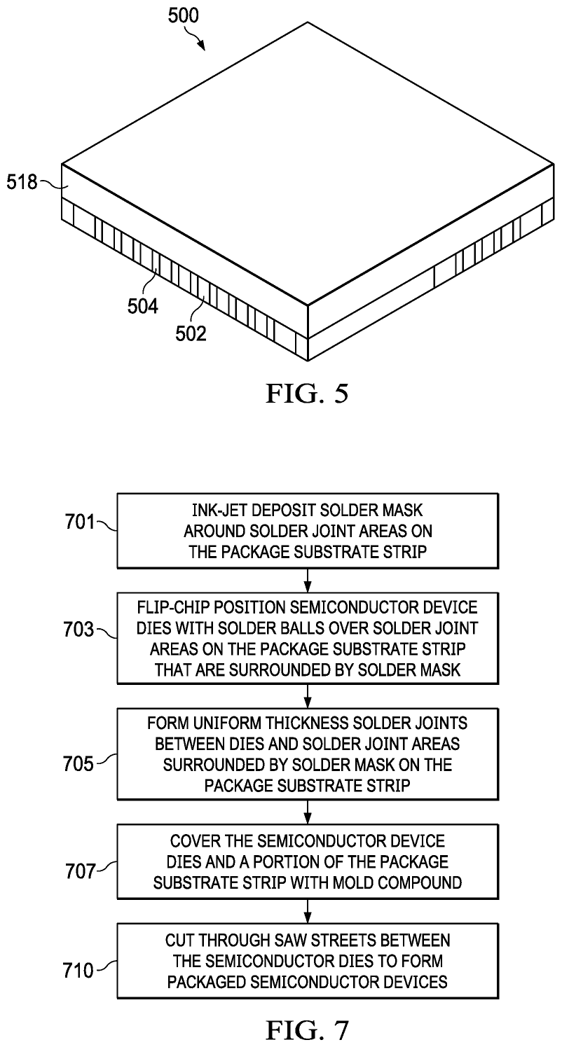

FIG. 5 is a projection view of a packaged semiconductor device in a quad, flat, no-lead (QFN) package 500. A portion of the surface of leads of the substrate 502 remain exposed (not covered by pre-mold compound 504 and not covered by mold compound 518) to form external terminals of the packaged semiconductor device 500 and facilitate electrical connection (and mounting) of the QFN 500 to another substrate such as a circuit board.

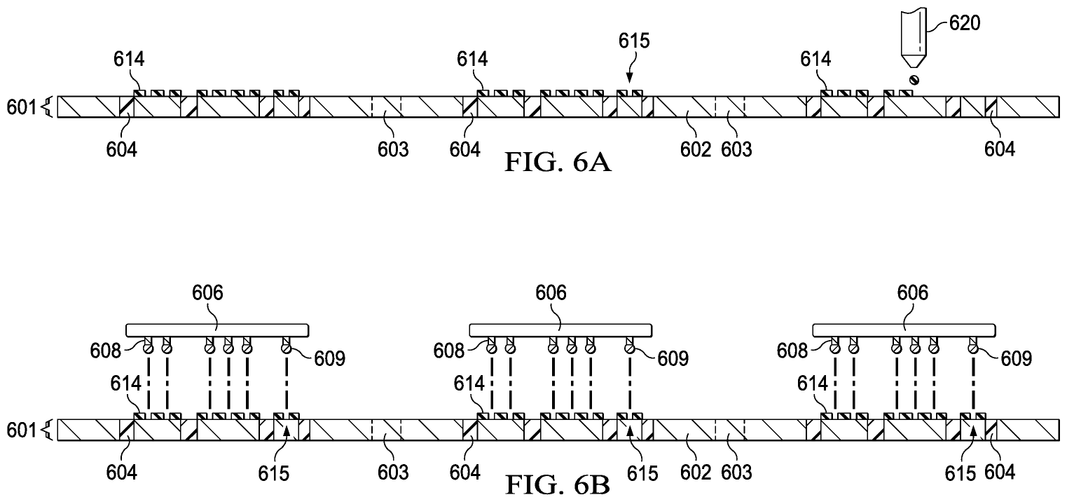

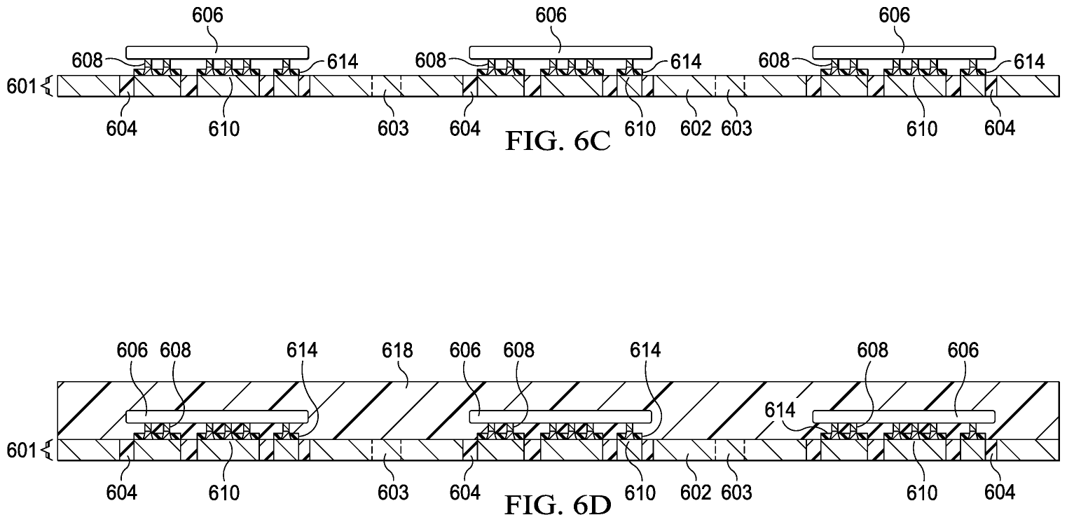

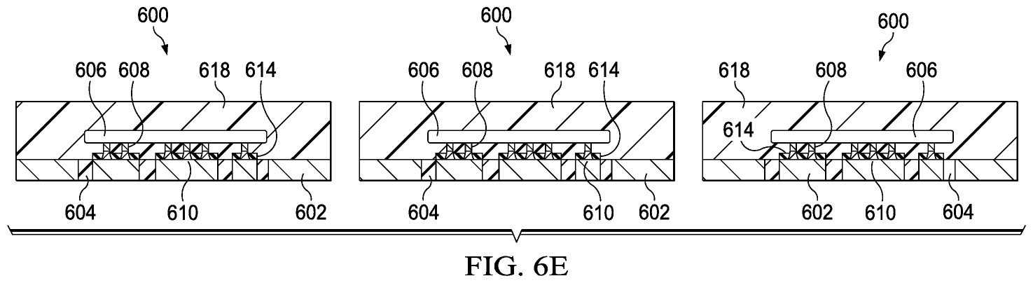

Cross sections in FIGS. 6A-6E illustrate example steps in the manufacture of the packaged semiconductor device 100 shown in FIG. 1. In FIGS. 6A-6E similar reference labels are used for similar elements shown in FIG. 1, for clarity. For example, semiconductor dies 606 in FIGS. 6A-6E correspond to die 106 in FIG. 1. The flow diagram of FIG. 7 describes corresponding method steps.

In FIG. 6A, step 701 (FIG. 7), a solder mask 614 is deposited onto the surface of a strip 601 of substrates, the solder mask 614 surrounding areas where solder joints 610 (see FIG. 6C) are to be formed. FIG. 6A shows a cross section of a portion of a substrate strip 601 in which three substrates 602 are connected together with saw streets 603 made of substrate material. The substrate 602 is usually copper or a copper alloy. Pre-mold compound 604 such as a filled epoxy resin, occupies the spaces between the leads of the substrate 602. Substrate 602 can also be of conductive lead frames without the pre-mold compound 604. In FIG. 6A, the solder mask 614 is deposited on the surface of the substrate 602 surrounding the regions 615 where solder joints 610 are to be formed. Various solder mask 614 deposition methods, such as screen printing and ink jet deposition can be used. Ink jet deposition by a nozzle such as 620 is preferred because ink jet deposition uses solder mask 614 material more efficiently than other methods, generates less environmentally harmful waste, and can deposit solder mask 614 geometries with a tighter pitch. For example, a solder mask 614 geometry about 50 μm wide can be deposited. In an arrangement a solder mask 614 geometry about 80 μm wide is deposited between solder joint regions 615. The solder mask 614 geometry is deposited with a thickness greater than about 15 μm. In an example arrangement the solder mask pattern 514 is deposited with a thickness of 20 μm. Solder mask useful with the arrangements can be any material used or useful for preventing solder from flowing such as alumina, silicon carbide, and silicon nitride. The solder mask 514 can be a polymer deposited using ink jet deposition. Example solder mask 514 materials include DiPaMat SM G01 (commercially available from Agfa), SMI100 (commercially available from Adeon), and SMI-200F (commercially available from Adeon).

As integrated circuit die continue to scale to smaller dimensions, the width and spacing (pitch) of copper pillars will continue to get smaller. Methods for depositing narrower width solder mask geometries will be developed to accommodate the smaller pillar pitches as the scaling continues. The arrangements are useful with conductive pillars of various pitches including smaller pitches that will be used.

After the material 614 is deposited, the material 614 can be cured at a temperature between 150° C.-200° C. for a time of up to one hour. The curing drives off excess solvent and can cross link the polymeric material to form ink residue. Alternatively, a photo curable material 614 can be deposited and cured with exposure to light or UV energy, depending on the material selected. The remaining ink residue from the ink jet deposition is the solder mask.

In FIG. 6B, step 703 (FIG. 7) a semiconductor die 606 with solder balls 609 atop copper posts 608 is positioned over each of the lead frames 602 in the lead frame strip 601 (“flip-chip” mounting with the device side of the die facing the substrate). The solder bumps 609 are positioned above solder joint regions 615 that are surrounded by the solder mask 614.

In FIG. 6C, step 705 (FIG. 7), the solder balls 609 are brought into contact with the solder joint regions 615 on the surface of the lead frames 602 and are melted to form solder joints 610 between the copper posts 608 and the surface of the lead frame 602. The solder mask 614 surrounding the solder joint 610 prevents melted solder from flowing outside the solder joint region 615 and away from the solder joint 610. This forms solder joints 610 with uniform thickness between the surface of the substrate 602 and the copper posts 608.

In FIG. 6D, step 707 (FIG. 7), the upper surface of the substrate strip 601 (as oriented in FIGS. 6A-6E, the upper surface of the substrate is the surface the devices 606 are being mounted to), the solder joints 610, the copper posts 608 and the semiconductor dies 606 are covered with mold compound 618 such as a filled epoxy or a filled polyimide. As described hereinabove, portions of the substrate and the conductive leads are not covered by the mold compound to form terminals for the packaged device.

In FIG. 6E, step 710 (FIG. 7), the mold compound 618 and the substrate strip 601 is cut through along the saw streets 603 to singulate the substrates 602 and to form individual packaged semiconductor devices 600, These packaged semiconductor devices 600 have solder joints 610 with uniform thicknesses coupling the semiconductor dies 606 to the substrates 602.

Modifications are possible in the described arrangements, and other alternative arrangements are possible within the scope of the claims.

1. An apparatus, comprising:
a semiconductor die including a bond pad electrically connected to a circuitry in the semiconductor die;
a conductive post on the bond pad;
a solder joint electrically connecting the conductive post to a substrate; and
ink residue of solder mask material contacting and surrounding a portion of the solder joint, the ink residue covering a portion of the substrate.

2. The apparatus of claim 1, wherein the ink residue is an ink-jet deposited material.

3. The apparatus of claim 1, wherein the ink residue is one selected from a group consisting essentially of: DiPaMat SM G01 (Agfa), SMI100 (Adeon), and SMI-200F (Adeon).

4. The apparatus of claim 1, wherein the ink residue is at least 15 μm thick.

5. The apparatus of claim 1, wherein an ink residue geometry surrounding a solder joint region is at least about 50 μm wide.

6. The apparatus of claim 1, wherein the conductive post is directly on the bond pad, and the conductive post comprises copper or copper alloy.

7. A method for forming an apparatus, comprising:
ink-jet depositing material forming an ink residue surrounding a portion of a solder joint area and covering a portion of a surface of a substrate;
bringing a solder bump that is atop a conductive post, the conductive post directly on a bond pad of a semiconductor die, into contact with the solder joint area; and
melting the solder bump and forming a solder joint between the conductive post and the surface of the substrate, the solder joint partially surrounded by the ink residue.

8. The method of claim 7, where the ink residue is a solder mask material.

9. The method of claim 8, wherein the solder mask is one selected from a group consisting essentially of: DiPaMat SM G01 (Agfa), SMI100 (Adeon), and SMI-200F (Adeon).

10. The method of claim 7, and further comprising, after the ink jet deposition, curing the ink at a temperature between 150° C.-200° C.

11. The method of claim 7, wherein depositing the material comprises depositing solder mask with a thickness of at least 15 μm.

12. The method of claim 7, wherein a geometry of the ink residue is deposited with a width of at least 50 μm.

13. A method for forming a packaged semiconductor device, comprising:
ink jet depositing a material on a substrate, forming ink residue around a portion of a solder joint area on a surface of substrates on a substrate strip;
bringing solder atop conductive posts on a bond pad on a semiconductor die into contact with the substrate in a solder joint area;
melting the solder to electrically connect the conductive posts and the surface of the substrates, the ink residue surrounding a portion of the solder joint areas and covering a portion of the substrates;
covering the surface of the substrates, the solder, the ink residue, the conductive posts, and the semiconductor dies with mold compound; and
cutting through the mold compound and the substrate strip along saw streets between substrates of the substrate strip to singulate packaged semiconductor devices.

14. The method of claim 13, wherein ink jet depositing the material further comprises performing an ink-jet deposition of solder mask material.

15. The method of claim 14, wherein the solder mask is a material that is one selected from a group consisting essentially of: DiPaMat SM G01 (Agfa), SMI100 (Adeon), and SMI-200F (Adeon).

16. The method of claim 13, and further comprising curing the material after the depositing at a temperature between 150° C.-200° C.

17. The method of claim 13, wherein depositing the material comprises depositing material with a thickness of at least 15 μm.

18. The method of claim 13, wherein depositing the material further comprises forming a geometry of the material with a width of at least 50 μm.

19. The method of claim 13, wherein the substrate comprises a copper lead frame.

20. The method of claim 13, wherein the substrate comprises a pre-molded lead frame.
